(19) United States
(12) Patent Application Publication
(10) Pub. No.: US 2026/0043125 A1
(43) Pub. Date: Feb. 12, 2026

(54) DEPOSITION METHOD, SPUTTERING APPARATUS, AND ROTARY TARGET

(71) Applicant: Japan Display Inc., Tokyo (JP)

(72) Inventors: Masanobu IKEDA, Tokyo (JP); Masumi NISHIMURA, Tokyo (JP); Ryoichi MATSUMOTO, Tokyo (JP)

(73) Assignee: Japan Display Inc., Tokyo (JP)

(21) Appl. No.: 19/359,815

(22) Filed: Oct. 16, 2025

Related U.S. Application Data
(63) Continuation of application No. PCT/JP2024/010481, filed on Mar. 18, 2024.

(30) Foreign Application Priority Data
Apr. 17, 2023 (JP) 2023-067235

(51) Int. Cl. C23C 14/34; C23C 14/06; C23C 14/50

(52) U.S. Cl. CPC C23C 14/3414; C23C 14/0617; C23C 14/3464; C23C 14/50

(57) ABSTRACT

The deposition method includes performing sputtering on a plurality of rotary targets arranged so that rotation axes thereof are parallel to one another while moving a substrate in a direction perpendicular to the rotation axes. The plurality of rotary targets is each positioned on one side of the substrate. The plurality of rotary targets includes a first rotary target and a second rotary target having a smaller radius than the first rotary target.

### CROSS-REFERENCE TO RELATED APPLICATIONS

This application is a Continuation of International Patent Application No. PCT/JP2024/010481, filed on Mar. 18, 2024, which claims the benefit of priority to Japanese Patent Application No. 2023-067235, filed on Apr. 17, 2023, the entire contents of which are incorporated herein by reference.

### FIELD

An embodiment of the present invention relates to a deposition method using a sputtering method. Alternatively, an embodiment of the present invention relates to a sputtering apparatus and a rotary target for realizing the deposition method.

### BACKGROUND

Transistors and capacitor elements constructing semiconductor devices are fabricated by stacking a plurality of thin films of appropriately patterned conductors, insulators, and semiconductors. One of the typical methods to fabricate these thin films is a sputtering method. Recently, it has been found that highly crystalline thin films can be fabricated by sputtering nitrides of Group 13 elements such as gallium nitride (GaN) and indium nitride (InN) which have been expected to be wide-gap semiconductors (see, International Patent Publication No. 2020/075599, Japanese Laid-Open Patent Publications No. 2008-270749 and 2019-147976, International Patent Publication No. 2022/070922, and Japanese Laid-Open Patent Publication No. 2017-179529).

### SUMMARY

An embodiment of the present invention is a deposition method. This deposition method includes performing sputtering on a plurality of rotary targets arranged so that rotation axes thereof are parallel to one another, while moving a substrate in a direction perpendicular to the rotation axes. The plurality of rotary targets is each arranged on one side of the substrate. The plurality of rotary targets includes a first rotary target and a second rotary target having a smaller radius than the first rotary target.

An embodiment of the present invention is a sputtering apparatus. The sputtering apparatus includes a chamber as well as a substrate stage, a plurality of target holders, and a moving mechanism which are arranged in the chamber. The plurality of target holders is each configured to hold a rotary target and arranged on one side of the substrate stage so that the rotation axes of the rotary targets are parallel to one another. The plurality of target holders includes a first target holder and a second target holder. The moving mechanism is configured to move the substrate stage in a direction perpendicular to the rotation axes. A radius of the rotary target to be held by the second rotary target is smaller than a radius of the rotary target to be held by the first rotary target.

An embodiment of the present invention is a rotary target. The rotary target includes a backing tube and a coating material covering the backing tube. The coating material has n 1/n-tube sections arranged to surround the backing tube. The 1/n-tube sections respectively contain materials different from each other. n is a natural number equal to or greater than 2.

### BRIEF DESCRIPTION OF DRAWINGS

FIG. 1 is a schematic view of a sputtering apparatus according to an embodiment of the invention.

FIG. 2A is a schematic side view of a portion of a sputtering apparatus according to an embodiment of the present invention.

FIG. 2B is a schematic cross-sectional view of a portion of a sputtering apparatus according to an embodiment of the present invention.

FIG. 3A is a schematic cross-sectional view of a rotary target according to an embodiment of the present invention.

FIG. 3B is a schematic cross-sectional view of a rotary target according to an embodiment of the present invention.

FIG. 4 is a schematic cross-sectional view of a rotary target according to an embodiment of the present invention.

FIG. 5A is a schematic cross-sectional view showing an arrangement of a substrate and rotary targets in a sputtering apparatus according to an embodiment of the present invention.

FIG. 5B is a schematic top view of showing an arrangement of a substrate and rotary targets in a sputtering apparatus according to an embodiment of the present invention.

FIG. 6A is a schematic cross-sectional view showing an arrangement of a substrate and rotary targets in a sputtering apparatus according to an embodiment of the present invention.

FIG. 6B is a schematic top view showing an arrangement of a substrate and rotary targets in a sputtering apparatus according to an embodiment of the present invention.

FIG. 7 is a schematic cross-sectional view showing an arrangement of a substrate and rotary targets in a sputtering apparatus according to an embodiment of the present invention.

FIG. 8A is a schematic cross-sectional view of a stacked member formed by a deposition method according to an embodiment of the present invention.

FIG. 8B is a schematic cross-sectional view illustrating a deposition method according to an embodiment of the present invention.

FIG. 8C is a schematic cross-sectional view illustrating a deposition method according to an embodiment of the present invention.

FIG. 9A is a schematic cross-sectional view illustrating a deposition method according to an embodiment of the present invention.

FIG. 9B is a schematic view illustrating a deposition method according to an embodiment of the present invention.

FIG. 10A is a schematic view illustrating a deposition method according to an embodiment of the present invention.

FIG. 10B is a schematic view illustrating a deposition method according to an embodiment of the present invention.

FIG. 10C is a schematic view illustrating a deposition method according to an embodiment of the present invention.

FIG. 11 is a schematic cross-sectional view of a light-emitting element manufactured using a sputtering apparatus according to an embodiment of the present invention.

FIG. 12A is a schematic cross-sectional view of a transistor manufactured using a sputtering apparatus according to an embodiment of the present invention.

FIG. 12B is a schematic cross-sectional view of a transistor manufactured using a sputtering apparatus according to an embodiment of the present invention.

### DESCRIPTION OF EMBODIMENTS

Hereinafter, each embodiment of the present invention is explained with reference to the drawings. The invention can be implemented in a variety of different modes within its concept and should not be interpreted only within the disclosure of the embodiments exemplified below.

The drawings may be illustrated so that the width, thickness, shape, and the like are illustrated more schematically compared with those of the actual modes in order to provide a clearer explanation. However, they are only an example, and do not limit the interpretation of the invention. In the specification and the drawings, the same reference number is provided to an element that is the same as that which appears in preceding drawings, and a detailed explanation may be omitted as appropriate. The reference number is used when plural structures which are the same as or similar to each other are collectively represented, while a hyphen and a natural number are further used when these structures are independently represented.

In the specification and the claims, unless specifically stated, when a state is expressed where a structure is arranged “over” another structure, such an expression includes both a case where the substrate is arranged immediately above the “other structure” so as to be in contact with the “other structure” and a case where the structure is arranged over the “other structure” with an additional structure therebetween.

In the specification and the claims, an expression “a structure is exposed from another structure” means a mode in which a part of the structure is not covered by the other structure and includes a mode where the part uncovered by the other structure is further covered by another structure. In addition, a mode expressed by this expression includes a mode where a structure is not in contact with other structures.

In the specification and the claims, an expression “a structure is exposed from another structure” means a mode in which a part of the structure is not covered by the other structure and includes a mode where the part uncovered by the other structure is further covered by another structure. In addition, a mode expressed by this expression includes a mode where a structure is not in contact with other structures.

Hereinafter, a sputtering apparatus, a rotary target, and a deposition method using the sputtering apparatus and the rotary target are described.

### 1. Sputtering Apparatus

### (1) Overall Structure

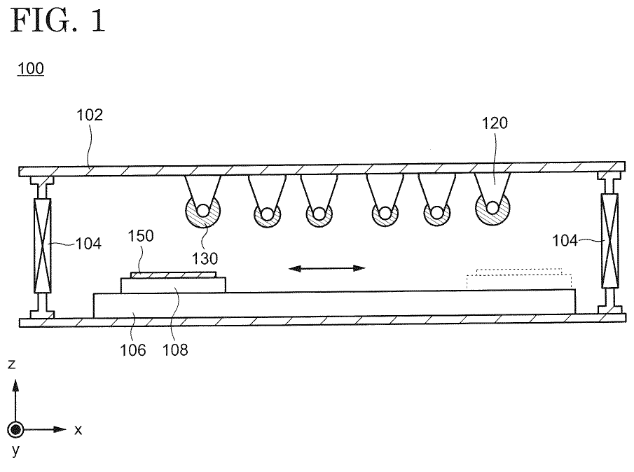

FIG. 1 shows a schematic view including a cross section of the sputtering apparatus 100 according to this embodiment. The sputtering apparatus 100 is a deposition apparatus with the capability to fabricate thin or ultra-thin films of conductors, semiconductors, or insulators over a substrate 150 by a sputtering method. The sputtering apparatus 100 includes a chamber 102, thereby providing a space for the collision of high-speed ions with sputtering targets and the deposition of target atoms generated in the collision. The chamber 102 is provided with one or a plurality of load lock doors 104, and the substrate 150 is introduced into and removed from the chamber 102 through the load lock doors 104.

There are no restrictions on the substrates 150 which can be used in the sputtering apparatus 100, and the substrate 150 may be a single-crystal substrate or an amorphous substrate. For example, a silicon substrate, a sapphire substrate, and a quartz substrate as well as a glass substrate and a plastic substrate can be used as the substrate 150. For example, a large rectangular amorphous glass substrate, also called a mother glass, can be used as the substrate 150. Specifically, a glass substrate with a size of 2160 mm×2460 mm also called the 8th generation mother glass, a glass substrate with a size of 2400 mm×2800 mm also called the 9th generation mother glass, a glass substrate with a size of 2880 mm×3130 mm also called the 10th generation mother glass, or a yet larger glass substrate may be used. Materials included in a plastic substrate include a polymer such as a polyimide, a polyamide, and a polycarbonate. The substrate 150 may be flexible.

A plurality of target holders 120 each configured to hold a rotary target 130 is arranged in an upper portion of the chamber 102. The plurality of target holders 120 is arranged so that the rotation axes of the plurality of rotary targets 130 are parallel to one another. The number of target holders 120 is not limited and may be equal to or more than 2 and equal to or less than 10, for example. A substrate stage 108 for placing the substrate 150 over which thin films are to be formed and a moving mechanism 106 for moving the substrate stage 108 are provided at a lower portion of the chamber 102. The moving mechanism 106 is configured to reversibly move the substrate stage 108 in a direction perpendicular to the rotation axes of the target holders 120. This feature allows the substrate 150 arranged on the substrate stage 108 to be moved relative to the plurality of rotary targets 130. There are no restrictions on the configuration of the moving mechanism 106, and a combination of one or a plurality of rails and wheels placed on the rails, a combination of a rack and a pinion gear, a combination of a belt and a plurality of pulleys, a combination of a chain and a gear, and the like may be employed as the moving mechanism 106, for example. Hereinafter, the direction in which the substrate 150 is moved by the moving mechanism 106 is defined as a x direction, the vertical direction is defined as a z direction, and the direction perpendicular to the x direction and the z direction is defined as a y direction (i.e., the direction in which the rotation axes of the rotary targets extend), for convenience.

Although not illustrated, an exhaust device for reducing the pressure in the chamber 102, one or a plurality of gas-introduction pipes for introducing sputtering gases such as argon, nitrogen, oxygen, and hydrogen into the chamber 102, and the like are connected to the chamber 102. A power supply for plasma generation connected to the substrate stage 108 and the rotary targets 130 is also provided to the sputtering apparatus 100. This power supply for plasma generation may be a high-frequency power supply, a direct current power supply, or a pulse power supply. In addition, an electrostatic chuck for fixing the substrate 150 onto the substrate stage 108, a power supply for the electrostatic chuck, a heater power supply for heating the substrate stage 108, a controller for controlling the temperature of a cooling medium to be circulated in the substrate stage 108, and the like may be provided to the sputtering apparatus 100.

Although the plurality of target holders 120 is arranged over the substrate stage 108 in the example demonstrated in FIG. 1, the configuration of the sputtering apparatus 100 is not limited thereto. For example, the substrate stage 108 may be positioned over the plurality of target holders 120. Alternatively, the substrate stage 108 may be arranged so that a normal line of the substrate 150 is in the horizontal direction, and the plurality of target holders 120 may be vertically arranged. In either configuration, all of the plurality of target holders 120 is positioned on one side of the substrate stage 108 and the substrate 150.

### (2) Target Holder

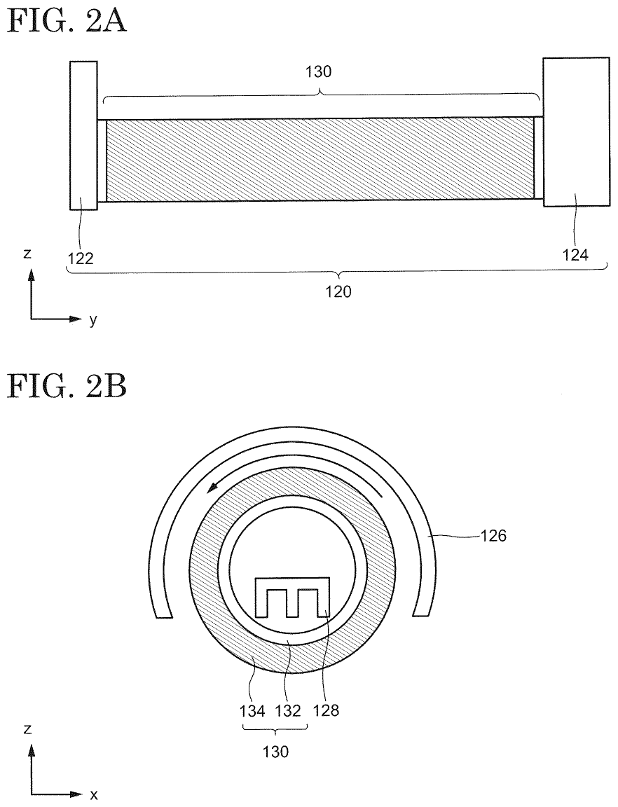

Schematic side and cross-sectional views of the rotary target 130 and the target holder 120 are respectively shown in FIG. 2A and FIG. 2B. As can be understood from these drawings, the target holder 120 has a control unit 124 for rotating the rotary target 130 about its rotation axis and connecting the rotary target 130 and the power supply for plasma generation to control the potential supplied to the rotary target 130 as well as a bearing 122. The rotary target 130 is mounted and held between the control unit 124 and the bearing 122. As an optional component, the sputtering apparatus 100 may have an anti-contamination plate 126 to prevent contamination by the materials ejected from the coating material 134 in unintended directions.

### (3) Rotary Target

The rotary target 130 includes, as its basic components, a backing tube 132 having a tubular shape and a coating material 134 covering the backing tube 132. Although not illustrated, the rotary target 130 may have a binder between the backing tube 132 and the coating material 134 to reinforce the bonding therebetween as an optional component. There is no restriction on the length of the rotary target 130 (length in the direction of the rotation axis), and the length is preferred to be longer than one side or the shortest diameter of the substrate 150 or the substrate stage 108. When a rectangular glass substrate is used as the substrate 150, the length of the rotary target 130 is preferred to be longer than the short side of the substrate 150 or the substrate stage 108. As described below, this relationship allows a film of the material contained in the coating material 134 to be formed over the entire surface of the substrate 150.

The backing tube 132 is electrically conductive and is connected to the power supply for plasma generation via the control unit 124 to receive a potential supply. A magnet 128 such as a permanent magnet connected to the control unit 124 is arranged in the backing tube 132. A potential is supplied to the backing tube 132 by the control unit 124, and the backing tube 132 is rotated by a rotation mechanism (not illustrated) included in the control unit 124, by which the coating material 134 is rotated. However, the magnet 128 is independent from the rotation of the backing tube 132 and is positioned on the side of the substrate stage 108 rather than the rotation axis while the backing tube 132 is rotating. This configuration allows the plasma generated by the power supply for plasma generation to always be localized on the substrate stage 108 side of the coating material 134, by which the portion of the coating material 134 exposed to the plasma is sputtered. The travel direction (scattering angle) of the materials ejected by sputtering can be arbitrarily adjusted by adjusting the magnetic force of the magnet 128 to control the region where the plasma is formed.

The coating material 134 contains materials constituting the films formed over the substrate 150. Collision of ions of a sputtering gas having high velocity with the coating material 134 sputters the materials contained in the coating material 134, and the materials are deposited over the substrate 150 to form a film. There are no restrictions on the materials contained in the coating material 134. For example, a metal (0-valent metal) such as aluminum, cobalt, chromium, molybdenum, niobium, titanium, tungsten, zinc, silver, gold, iron, and iridium, an alloy thereof, an oxide such as aluminum oxide, copper oxide, chromium oxide, cesium oxide, and magnesium oxide, titanium oxide, tungsten oxide, and strontium titanate, a nitride such as aluminum nitride, chromium nitride, and silicon nitride, a non-metallic element such as silicon, boron, carbon, and germanium, and a compound semiconductor are represented. The oxide may be a conductive oxide transmitting visible light such as indium-tin mixed oxide (ITO) and indium-zinc mixed oxide (IZO). Compound semiconductors include a gallium nitride-based compound semiconductor such as gallium nitride, aluminum gallium nitride, and indium gallium nitride as well as a gallium phosphide-based compound semiconductor such as gallium phosphide, aluminum indium gallium phosphide, indium gallium arsenide phosphide, an indium-based compound semiconductor such as indium phosphide, silicon carbide, and the like. The coating material 134 may contain a dopant such as silicon, germanium, magnesium, zinc, cadmium, and beryllium.

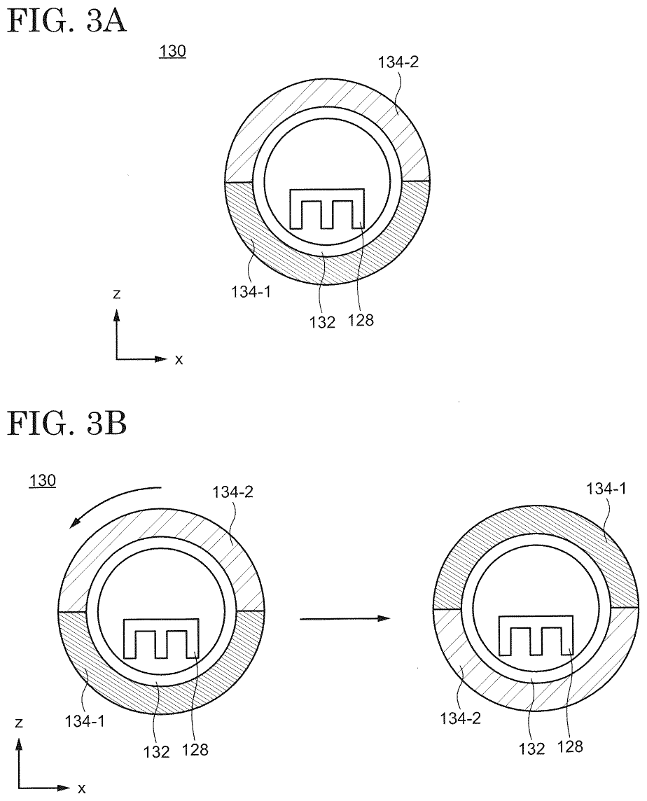

In each rotary target 130, there may be one or more types of material in the coating material 134. That is, the coating material 134 may have a plurality of regions having different compositions. For example, the coating material 134 of the rotary target 130 according to an embodiment of the present invention may have two half-tube sections (first half-tube section 134-1 and second half-tube section 134-2) sandwiching the backing tube 132 and facing each other as shown in FIG. 3A. The first half-tube section 134-1 and the second half-tube section 134-2 include materials of different compositions from each other. For example, when the coating material 134 contains gallium nitride-based compound semiconductors, the first half-tube section 134-1 and the second half-tube section 134-2 may contain gallium nitride-based compound semiconductors of different compositions (gallium nitride and indium gallium, etc.). Thus, when the coating material 134 has a plurality of regions of different compositions, the rotation of the rotary target 130 allows the first half-tube section 134-1 and the second half-tube section 134-2 to be alternately exposed to plasma (FIG. 3B) because the plasma can be localized between the rotary target 130 and the substrate 150 by the magnet 128. As a result, materials of different compositions can be alternately ejected from one rotary target 130, leading to the fabrication of alternating stacked films with different compositions.

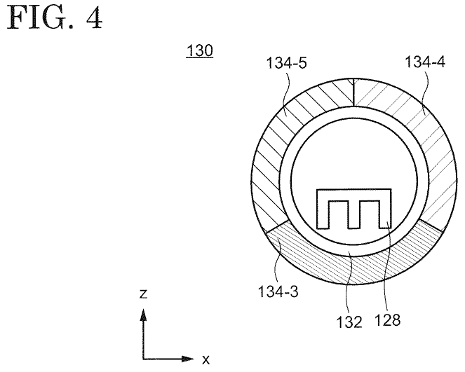

The number of regions with different compositions in the coating material 134 is not limited to two and may be three or more. For example, the coating material 134 may have three ⅓-tube sections 134-3 to 136-5 arranged to surround the backing tube 132 and having different compositions from one another as shown in FIG. 4. Generalizing, the coating material 134 of the rotary target 130 according to an embodiment of the present invention may have n 1/n-tube sections arranged to surround the backing tube 132 and having different compositions from one another, and the rotation of the rotary target 130 allows the first to nth films with different compositions to be formed sequentially and repeatedly. Here, n is a natural number equal to or greater than 2.

### (4) Arrangement of Rotary Target and Substrate

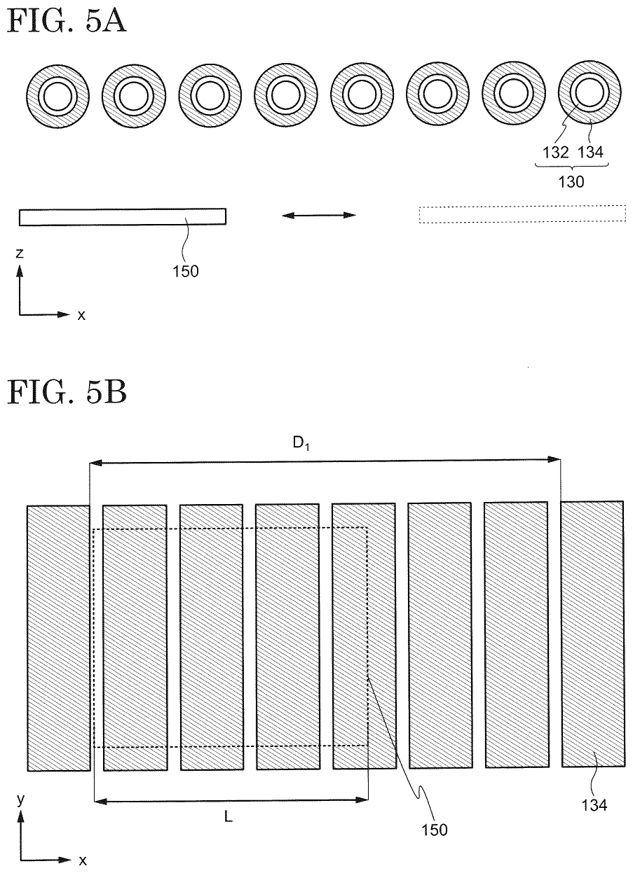

The arrangement relationship between the rotary targets 130 and the substrate 150 is explained using the schematic cross-sectional and top views respectively shown in FIG. 5A and FIG. 5B. As described above, each of the plurality of rotary targets 130 is longer than the short side of the substrate 150 and is arranged on one side of the substrate 150 or the substrate stage 108 so that their rotation axes are parallel to one another. The plurality of rotary targets 130 is further arranged so that the maximum distance (distance D₁ in FIG. 5B) between two of the rotary targets 130 is greater than the length L of the substrate 150 in the longitudinal direction. It is possible to deposit the material over the entire surface of the substrate 150 by employing this arrangement and sputtering the coating material 134 while moving the substrate 150 in the x direction. In addition, a plurality of layers containing different materials can be deposited by appropriately selecting the materials in the coating materials 134 of the plurality of rotary targets 130.

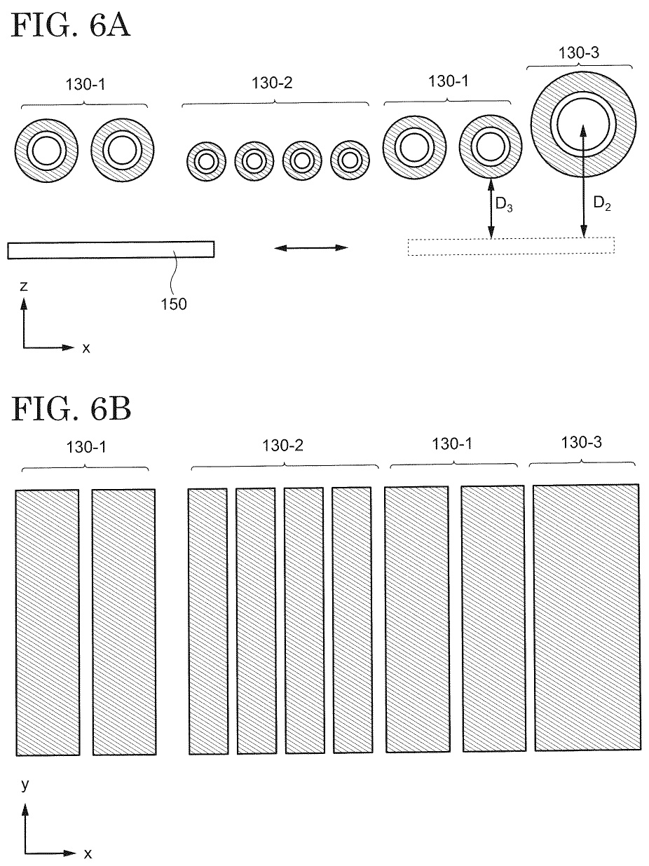

Furthermore, as can be understood from the schematic side and top views respectively demonstrated in FIG. 6A and FIG. 6B, the radii of the plurality of rotary targets 130 (or the outer diameters of the coating materials 134. The same is applied hereinafter) need not necessarily be identical, and the radius of at least one rotary target 130 may be different from the radii of the other rotary targets 130. In the example shown in FIGS. 6A and 6B, the rotary target 130-3 with the largest radius, the rotary targets 130-2 with the smallest radius, and the rotary targets 130-1 having a radius larger than the radius of the rotary target 130-2 and smaller than the radius of the rotary target 130-3 are arranged.

When the plurality of rotary targets 130 with different radii is used, the plurality of rotary targets 130 is arranged so that the distances D₂ from the substrate stage 108 or the substrate 150 to the rotation axes of the rotary targets 130 are different. More specifically, the plurality of rotary targets 130 is arranged so that the distances D₂ from the substrate stage 108 or the substrate 150 to the rotation axes of the rotary targets 130 increase with increasing radii of the rotary targets 130. Using the example shown in FIG. 6A, the plurality of rotary targets 130 is arranged so that the distances D₂ increase in the order of the rotary target 130-2, the rotary target 130-1, and the rotary target 130-3.

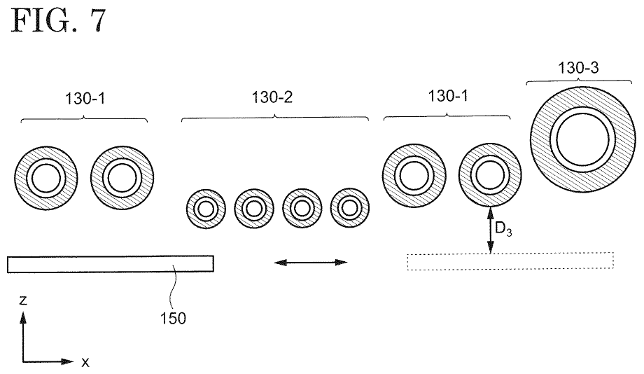

Note that the distances D₃ from the substrate 150 or the substrate stage 108 to the surfaces of the coating materials 134 may be substantially the same or different between the rotary targets 130. In the latter case, it is preferable to arrange the plurality of rotary targets 130 so that the distances D₃ from the substrate 150 or the substrate stage 108 to the surface of the coating materials 134 increase with increasing radii of the rotary targets 130 as shown in FIG. 7. In this case, the plurality of target holders 120 may also be configured so that the distances from the substrate 150 or the substrate stage 108 varies according to the radii of the rotary targets 130, or the distances from the rotation axes of the rotation mechanism of the control units 124 to the substrate stage 108 or the substrate 150. As described below, such an arrangement allows the formation of not only large-thickness films but also ultra-thin films with precisely controlled thicknesses.

### 2. Deposition Method

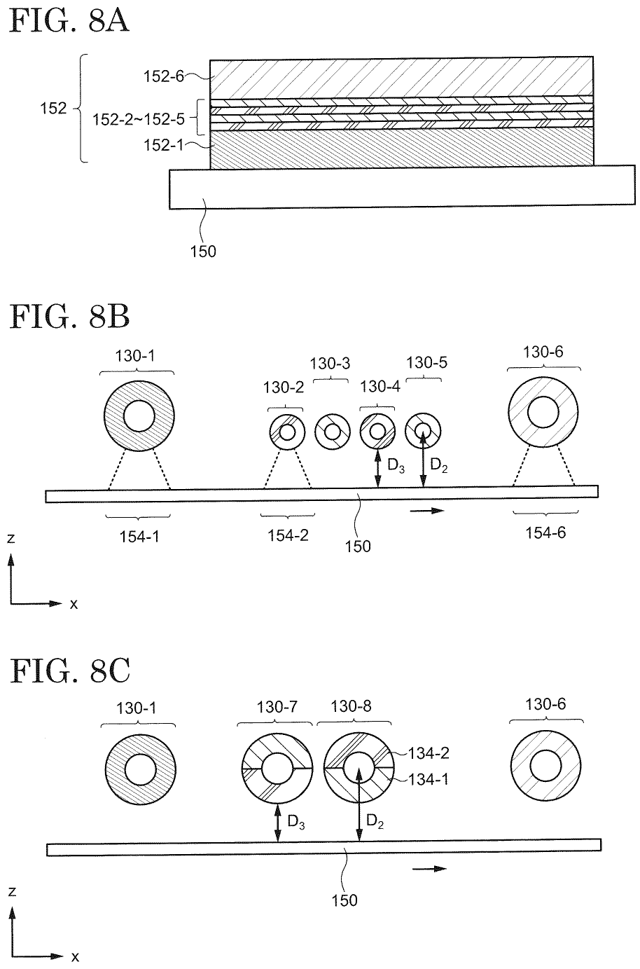

Hereinafter, a method for depositing a plurality of films over the substrate 150 using the sputtering apparatus 100 is explained. Here, a stacked member 152 including the films 152-1 to 152-6 shown in FIG. 8A is used as an example. The stacked member 152 is fabricated by sequentially depositing the films 152-1 to 152-6 over the substrate 150. In the stacked member 152, the films 152-2 to 152-5 with smaller thicknesses than the films 152-1 and 152-6 are sequentially stacked between the films 152-1 and 152-6 including different materials. In addition, the materials contained in the films 152-2 to 152-5 are also different from the materials contained in the films 152-1 and 152-6. The materials contained in the films 152-2 and 152-4 are identical to each other, and the materials contained in the films 152-3 and 152-5 are also identical to each other. However, the materials contained in the films 152-2 and 152-4 are different from the materials contained in the films 152-3 and 152-5. That is, the stacked member 152 is structured with four different materials.

(1) Deposition Method 1: Case Using Rotary Targets with Different Radii

When the rotary targets 130 with different radii are used, the rotary targets 130-1 to 130-6 in which the materials to be included in the films 152-1 to 152-6 are respectively contained in the coating materials 134 are sequentially arranged as shown in FIG. 8B. Furthermore, the rotary targets 130-1 to 130-6 are selected so that the rotary targets 130-2 to 130-5 for forming the smaller thickness films have smaller radii compared with the rotary targets 130-1 and 130-6 for forming the larger thickness films. Therefore, the rotary targets 130-1 to 130-6 are arranged so that the distances D₂ from the rotation axes of the rotary targets 130-2 to 130-5 to the substrate 150 are smaller than the distances D₂ from the rotation axes of the rotary targets 130-1 and 130-6 to the substrate 150. Although the distances D₃ from the surfaces of the coating materials 134 to the substrate 150 are the same between the rotary targets 130-1 to 130-6 in FIG. 8B, the rotary targets 130 may be arranged so that the distances D₃ decrease with decreasing radii of the rotary targets 130.

In this state, the pressure in the chamber 102 is reduced, and a potential difference is formed between the rotary targets 130 and the substrate 150 using the power supply for plasma generation while supplying a sputtering gas. Furthermore, the substrate stage 108 is moved at a constant speed from the rotary target 130-1 side to the rotary target 130-6 side using the moving mechanism 106. The scattering angle of the material ejected from the rotary target 130 is controlled by the magnet 128. Therefore, the region (deposition region) where the material ejected from each rotary target 130 is deposited can be limited within a certain range as shown by the dotted line in FIG. 8B. That is, the deposition region 154 of each rotary target 130 does not occupy the entire substrate 150 but is restricted to a certain width range centered on the region overlapping each rotary target 130.

Furthermore, as described above, the rotation axes of the rotary targets 130-2 to 130-5 for forming the smaller thickness films 152-2 to 152-5 are positioned closer to the substrate 150 than the rotation axes of the rotary targets 130-1 and 130-6 for forming the larger thickness films 152-1 and 152-6. Therefore, when the scattering angles of the materials ejected from the rotary targets 130-1 to 130-6 are identical, the deposition regions of the rotary targets 130-2 to 130-5 (e.g., the deposition region 154 in FIG. 5B) have a smaller width (length in the x direction) than the deposition regions 154-1 and 154-6 of the rotary targets 130-1 and 130-6. Since the substrate 150 is moved at a constant speed, the times for the substrate 150 to pass through the deposition regions 154-1 and 154-6 are longer than the times to pass through the deposition region 154-2. As a result, focusing on one point on the substrate 150, the film 152-1 is formed with a large thickness while passing through the deposition region 154-1, and then the film 152-2 is formed with a small thickness while passing through the deposition region 154-2. Since this point then passes through the deposition regions of the rotary targets 130-3 to 130-5 in sequence, the films 152-3 to 152-5 with smaller thicknesses are deposited in sequence. Finally, this point passes through the deposition region 154-6 having a relatively large width, resulting in the deposition of the film 152-6 with a larger thickness. Accordingly, the stacked member 152 including the plurality of films 152-1 to 152-6 with different thicknesses can be fabricated.

The thickness of each of the plurality of films 152-1 to 152-6 can be controlled by appropriately adjusting the movement speed of the substrate 150, the distances D₂ from the rotation axes of the rotary targets 130 to the substrate 150, the distances D₃ between the surfaces of the coating materials 134 and the substrate 150, the rotation speed of the rotary targets 130, and the like. For example, extremely thin films can be formed by decreasing the distances D₂ and/or the distances D₃ because the deposition regions decrease. Conversely, it is possible to form extremely thick films by increasing the distances D₂ and/or the distances D₃ because the deposition regions increase. Furthermore, the thicknesses of the plurality of films 152-1 to 152-6 may be controlled by adjusting the size of the magnet 128 or the range of the magnetic force as appropriate to control the region where plasma is generated for controlling the deposition region 154. For example, the scattering angle may be reduced by relatively decreasing the regions of plasma generated on the surfaces of the rotary targets 130 which provide the smaller thickness films 152-2 to 152-5. Conversely, the scattering angle may be increased by relatively increasing the regions of plasma generated on the surfaces of the rotary targets 130 which provide the larger thickness films 152-1 and 152-6. This methodology allows the time for the substrate 150 to pass through the deposition region 154 to be appropriately adjusted, thereby controlling the thicknesses of the plurality of films 152-1 to 152-6.

Note that, in this method, it is not always necessary to simultaneously form the films 152-1 to 152-6. For example, a potential is first supplied only to the rotary target 130-1 from the power supply for plasma generation while moving the substrate 150 in one direction (forward direction) to form the first film 152-1 over the entire surface of the substrate 150. Then, the potential is supplied to the rotary targets 130-2 to 130-5 while moving the substrate 150 in the reverse direction or while moving the substrate 150 in the forward direction after returning the substrate 150 to the position before the film 152-1 is formed to result in the films 15 2-2 to 152-5. After that, the potential may be supplied to the rotary target 130-6 while moving the substrate in the reverse direction or while moving the substrate 150 in the forward direction after returning the substrate 150 to the position before the film 152-1 is formed to result in the film 152-6. In this case, it is not always necessary to use the same number of rotary targets 130 as the number of films included in the stacked member 152. For example, one rotary target 130-2 for forming the films 152-2 and 152-4 and one rotary target 130-3 for forming the films 152-3 and 152-5 may be used, and the substrate 150 may be reciprocated in the x direction.

The aforementioned method enables the fabrication of ultra-thin films of several nanometers in thickness and thick films of up to several hundred nanometers, for example. Therefore, it is possible to precisely form, for example, quantum well structures employed in electroluminescent elements as well as active layers with extremely small-thickness in thin-film transistors.

(2) Deposition Method 2: Case Using Rotary Targets with Different Compositions

As the targets for forming a structure in which a plurality of films with small thicknesses is repeatedly deposited (here, the stacked layers of the films 152-2 to 152-5), the aforementioned rotary targets 130 each including a plurality of coating materials 134 having different compositions may be used. For example, the rotary target 130-1 for forming the film 152-1, a rotary target 130-7 for forming the films 152-2 and 152-3, a rotary target 130-8 for forming the films 152-4 and 152-5, and a rotary target 130-6 for forming the film 152-6 are arranged in order as shown in FIG. 8C. Here, the radii of the rotary targets 130-7 and 130-8 may be the same as or smaller than the radii of the rotary targets 130-1 and 130-6. Furthermore, the distance D₂ and the distance D₃ for the rotary targets 130-7 and 130-8 may also be smaller than those for the rotary targets 130-1 and 130-6.

In this state, the pressure in the chamber 102 is reduced, and a potential difference is formed between the rotary targets 130 and the substrate 150 using the power supply for plasma generation while supplying a sputtering gas. Furthermore, the substrate stage 108 is moved at a constant speed from the rotary target 130-1 side to the rotary target 130-6 side using the moving mechanism 106. Similar to the deposition method 1, this operation allows the films 152-1 to 152-6 to be deposited over the substrate 150 in order. Furthermore, since the period in which the first half-tube section 134-1 and the second half-tube section 134-2 are exposed to the plasma can be controlled by appropriately adjusting the rotation speed of the rotary targets 130-7 and 130-8, thicknesses of the films 152-2 to 152-5 can be adjusted.

In this deposition method 2, it is not always necessary to simultaneously supply the power supply for plasma generation to all of the rotary targets 130 to simultaneously form the films 152-1 to 152-6. Similar to the deposition method 1, the films 152-2 to 152-5 may be formed after forming the film 152-1 over the entire surface of the substrate 150, and then the film 152-6 may be formed.

(3) Deposition Method 3: Case Using Rotary Targets with the Same Radii

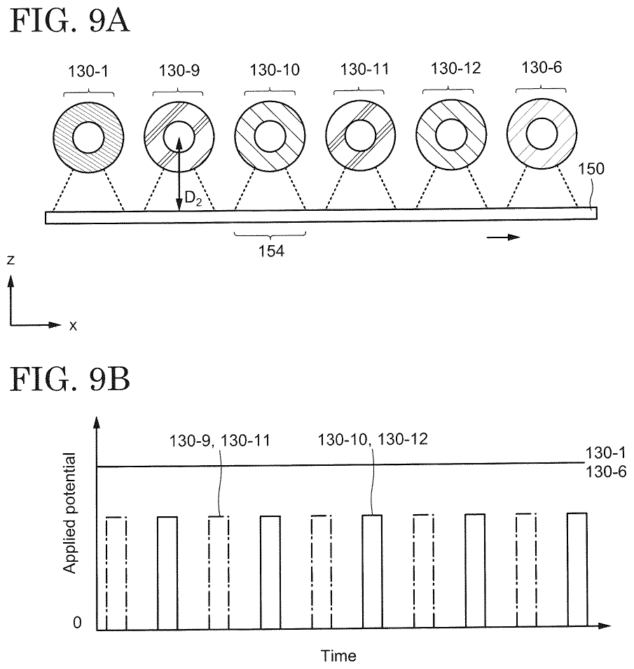

Even when the plurality of rotary targets 130 having the same or substantially the same radii is used as the targets respectively providing the films 152-1 to 152-6, the deposition method according to an embodiment of the present invention can be applied. In this case, the rotary targets 130-1, 130-9 to 130-12, and 130-6 respectively providing the films 152-1 to 152-6 are placed in sequence as shown in FIG. 9A. At this time, the distances D₂ between the substrate 150 and the rotation axes of the rotary targets 130 may be the same between all of the rotary targets 130 or may be different for some of the rotary targets 130. For example, the distances D₂ between the rotation axes of the rotary targets 130-9 to 130-12 and the substrate 150 may be smaller than that of the rotary targets 130-1 or 130-6 to decrease the width of the deposition region.

In this state, the pressure in the chamber 102 is reduced, and a potential difference is formed between the rotary targets 130 and the substrate 150 using the power supply for plasma generation while supplying a sputtering gas. Furthermore, the substrate stage 108 is moved at a constant speed from the rotary target 130-1 side to the rotary target 130-6 side using the moving mechanism 106. Similar to the deposition methods 1 and 2, this operation allows the films 152-1 to 152-6 to be deposited over the substrate 150 in order.

However, when the distances from the rotation axes of all of the rotary targets 130 to the substrate 150 are the same or substantially the same, the width of the deposition regions may be substantially the same, and consequently the thicknesses of the films 152-1 to 152-6 may be almost the same. Hence, the time for supplying the potential from the power supply for plasma generation to the rotary targets 130 is controlled in this method. Specifically, the potential is supplied to the rotary targets 130-1 and 130-6 for providing the thicker films 152-1 and 152-6 for the longest time. For example, when the power supply for plasma generation is a direct-current power supply, the potential is continuously supplied to the rotary targets 130-1 and 130-6 as shown in FIG. 9B. In contrast, the potential is intermittently supplied to each of the rotary targets 130-9 to 130-12 for forming the thin films 152-2 to 152-5 to adjust the time for supplying the potential to be shorter than that of the rotary targets 130-1 and 130-6. In addition, the rotary targets 130-9 and 130-11 for forming the films 152-2 and 152-4 and the rotary targets 130-10 and 130-12 for forming the films 152-3 and 152-5 are alternately supplied with the potential. The time for supplying the potential to the rotary targets 130 may be set appropriately considering the movement speed of the substrate 150.

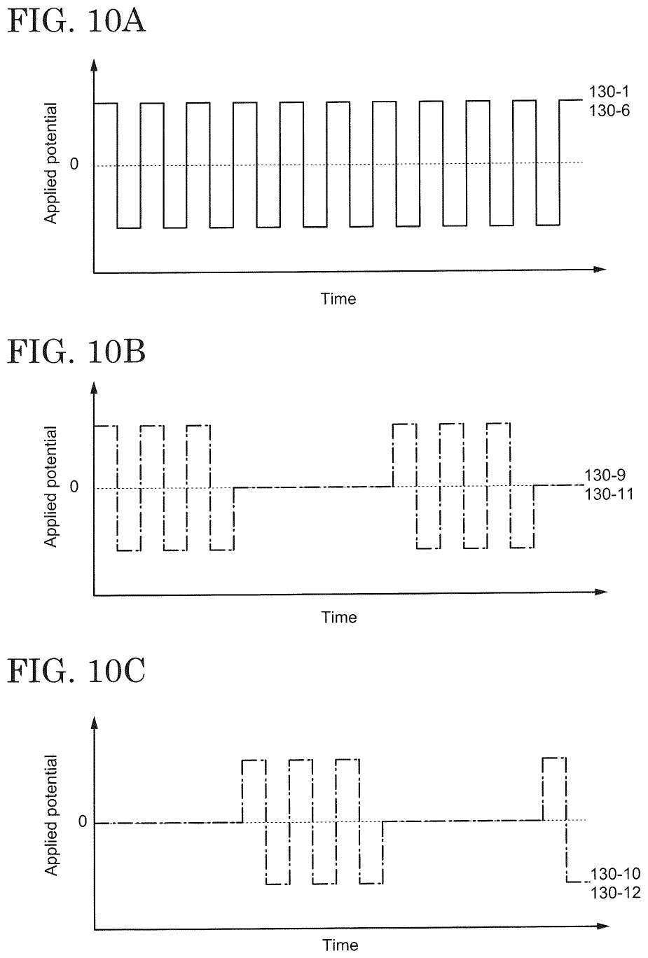

When the power supply for plasma generation is a high-frequency power source, the rotary targets 130-1 and 130-6 for forming the thick films 152-1 and 152-6 are supplied with the potential in a steady state while periodically changing its polarity as shown in FIG. 10A. In contrast, the rotary targets 130-9 to 130-12 for forming the thin films 152-2 to 152-5 are supplied with the potential intermittently while changing its polarity, whereas the pair of rotary targets 130-9 and 130-11 and the pair of rotary targets 130-10 and 130-12 are alternately supplied with the potential as shown in FIG. 10B and FIG. 10C. In this case, the time for supplying the potential to the rotary targets 130 may also be set appropriately in consideration of the movement speed of the substrate 150. This methodology allows the sputtering time for the plurality of rotary targets 130 to be adjusted so that the thicknesses of the plurality of films 152-1 to 152-6 can be controlled.

In this deposition method 3, it is not always necessary to form the films 152-1 to 152-6 at the same time. Similar to the deposition methods 1 and 2, the films 152-2 to 152-5 may be formed after the film 152-1 is formed over the entire surface of the substrate 150, and then the film 152-6 may be formed.

Note that the deposition methods 1 to 3 described above can be combined as appropriate. For example, in the deposition method 1, the rotary targets 130-2 to 130-5 having smaller radii than the radii of the rotary targets 130-1 and 130-6 for forming the thicker films 152-1 and 152-6 may be used for forming the thin films 152-2 to 152-5, and n 1/n-tube sections with different compositions may be provided to the coating materials 134 of the rotary targets 130-2 to 130-5. Alternatively, the time for supplying the potential may be controlled in the deposition method 1. For example, similar to the deposition method 3, the time for supplying the potential to the rotary targets 130-2 to 130-5 for forming the films with smaller thicknesses may be shorter than that for the rotary targets 130-1 and 130-6 for forming the films with larger thicknesses in the deposition method 1. Alternatively, the rotary targets 130-9 to 130-12 with smaller radii than the radii of the rotary targets 130-1 and 130-6 for forming the thick films 152-1 and 152-6 may be used to form the thin films 152-2 to 152-5 in the deposition method 3.

Similarly, the thicknesses of the films 152-1 to 152-6 may also be controlled by adjusting the time for supplying the potential from the power supply for plasma generation in the deposition method 2. Specifically, the time for supplying the potential to the rotary targets 130-7 and 130-8 is set to be shorter than that to the rotary targets 130-1 and 130-6. For example, the rotary targets 130-7 and 130-8 are intermittently supplied with the potential, while the rotary targets 130-1 and 130-6 are continuously supplied with the potential. Since this operation allows the sputtering time to be adjusted for the plurality of rotary targets 130, the thicknesses of the films 152-1 to 152-6 can be controlled. In addition, since pulse sputtering is performed on the rotary targets 130-7 and 130-8, the crystallinity of the resulting films 152-2 to 152-5 can be improved.

As described above, films of a wide range of thicknesses can be stacked in any order and with precisely controlled thicknesses by using the sputtering apparatus 100 and applying any of the deposition methods described above. In addition, since high temperatures are not necessarily required for film deposition by a sputtering method, large amorphous substrates (e.g., glass substrate or plastic substrate) can be used as the substrate 150 subjected to the film deposition. Therefore, implementation of an embodiment of the present invention enables the production of a variety of semiconductor devices at low cost.

### 3. Application

The sputtering apparatus 100 and the deposition method using the sputtering apparatus 100 described above can be applied to the manufacture of a variety of semiconductor devices. Semiconductor devices include light-emitting diodes, transistors, and the like.

### (1) Light-Emitting Diode

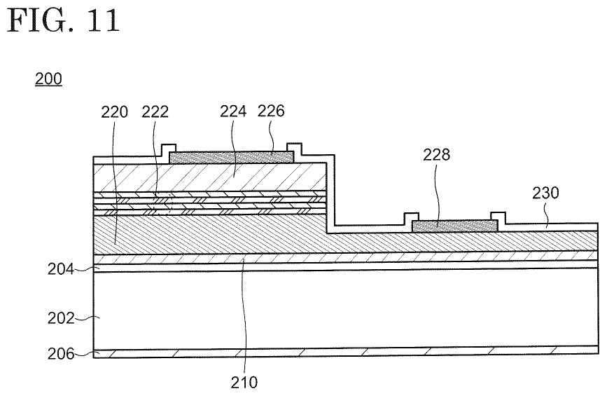

A schematic cross-sectional view of an example of a light-emitting diode 200 manufactured using the sputtering apparatus 100 is shown in FIG. 11. The light-emitting diode 200 has a substrate 202 and further has an n-type cladding layer 220 over the substrate 202 through a buffer layer 210. The light-emitting diode 200 further has a stacked member including a p-type cladding layer 224 over the n-type cladding layer 220 and an emission layer 222 sandwiched between the n-type cladding layer 220 and the p-type cladding layer 224. In addition, the light-emitting diode 200 has an anode 226 and a cathode 228 respectively disposed over the p-type cladding layer 224 and the n-type cladding layer 220. The light-emitting diode 200 may further include, as optional components, an overcoat 204 between the substrate 202 and the buffer layer 210, an undercoat 206 under the substrate 202, a protective film 230 over the anode 226 and cathode 228, and the like. When a potential difference above the emission threshold voltage is provided between the anode 226 and cathode 228, holes and electrons are respectively injected from the anode 226 and cathode 228, and the holes and electrons recombine in the emission layer 222 to produce light emission.

The substrate 202 supports each of the components provided thereover and may include not only quartz, single-crystal silicon, or single-crystal sapphire, but also amorphous glass such as alkali-free glass.

The overcoat 204, which is an optional component, is formed over the substrate 202 so as to be in contact with the substrate 202. The formation of the overcoat 204 prevents the diffusion of impurities such as alkali metal ions contained in the substrate 202. The overcoat 204 may be a single film or a stack of a plurality of films containing a silicon-containing inorganic compound such as silicon oxide and silicon nitride. The undercoat 206 suppresses elimination of water and the like from the substrate 202 under high temperature conditions during the manufacture of the light-emitting diode 200, prevents impurities containing oxygen from entering the n-type cladding layer 220, the emission layer 222, the p-type cladding layer 224, and the like, and prevents warpage of the substrate 202 caused by the difference in thermal expansion coefficient between the substrate 202 and the n-type cladding layer 220. A film containing aluminum nitride, a film containing aluminum oxide, or a stack thereof may be used as the undercoat 206.

The buffer layer 210 improves the adhesion between the substrate 202 and the n-type cladding layer 220 so that deformation (warpage) of the substrate 202 under high temperature conditions during the manufacture of the light-emitting diode 200 is prevented. Furthermore, the buffer layer 210 contributes to the crystallization of the n-type cladding layer 220 formed thereover in the c-axis direction. Hence, the crystallinity of the n-type cladding layer 220 as well as each layer formed thereover can also be improved. As a result, the light-emitting diode 200 with excellent characteristics can be provided. The buffer layer 210 may be configured to include titanium nitride, aluminum nitride, aluminum oxide, aluminum oxynitride, or the like. The buffer layer 210 may have a single-layer structure or a stacked-layer structure.

The n-type cladding layer 220, the emission layer 222, and the p-type cladding layer 224 are configured to emit visible light when the holes and the electrons respectively injected from the anode 226 and cathode 228 are recombined. The n-type cladding layer 220, the emission layer 222, and the p-type cladding layer 224 may each have a single layer structure or a stacked-layer structure in which a plurality of layers is stacked. For example, the n-type cladding layer 220 may be a stacked layer of a layer containing undoped gallium nitride without any dopants and a layer containing n-type gallium nitride with a dopant imparting n-type conductivity such as silicon and germanium. Although the n-type cladding layer 220, the emission layer 222, and the p-type cladding layer 224 are stacked in order from the substrate 202 side in the example shown in FIG. 11, the reverse order of this sequence may be adopted.

The n-type cladding layer 220, the emission layer 222, and the p-type cladding layer 224 are each a semiconductor layer containing a Group 13 element and a Group 15 element. Specifically, these layers include a semiconductor containing aluminum, gallium, and/or indium as well as nitrogen, phosphorus, and/or arsenic. A gallium-based material is represented as a typical semiconductor. For example, gallium nitride-based materials such as gallium nitride, aluminum gallium nitride (AlGaN), and indium gallium nitride (InGaN) and a gallium phosphide-based material such as gallium phosphide (GaP), aluminum indium gallium phosphide (AlGaInP) are represented. The n-type cladding layer 220 and the p-type cladding layer 224 may further contain the dopant described above. The addition of a dopant enables valence electron control and band gap control of each layer.

The emission layer 222 may have a single-layer structure of indium gallium nitride, for example, of may have a quantum well structure as shown in FIG. 11. A quantum well structure is a structure in which a plurality of thin films having different band gaps and extremely small thicknesses of 1 to 5 nm is stacked, and alternating layers of indium gallium nitride and gallium nitride, alternating layers of indium gallium arsenide phosphide (GaInAsP) and indium phosphide (InP), alternating layers of aluminum indium arsenide (AlInAs) and indium gallium arsenide (InGaAs), and the like are exemplified.

The anode 226 and the cathode 228 respectively inject holes and electrons into the p-type cladding layer 224 and n-type cladding layer 220. As the anode 226, a thin film of a metal such as palladium and gold, an alloy of these metals, or a conductive oxide transmitting visible light such as indium-tin mixed oxide (ITO) and indium-zinc mixed oxide (IZO) can be used, for example. A metal such as aluminum, titanium, gold, silver and indium or an alloy of these metals can be used as the cathode 228. Both the anode 226 and cathode 228 may have a single-layer structure or may be a stacked member having a plurality of films having different compositions.

The protective film 230 is a component to prevent impurities such as oxygen and water from entering the light-emitting diode 200 and is composed of one or a plurality of films containing a silicon-containing inorganic compound such as silicon oxide and silicon nitride, for example. The protective film 230 is provided with openings to expose the anode 226 and cathode 228, and wirings which are not illustrated are electrically connected to the anode 226 and cathode 228 using these openings.

The films of a variety of materials structuring the light-emitting diode 200 may be formed using a chemical vapor deposition (CVD) method or the sputtering method using the sputtering apparatus 100 and the deposition method described above. When the sputtering method is utilized, the film formation at the high temperatures required by the epitaxial growth using a CVD method such as metal organic chemical vapor deposition (MOCVD) is not necessary. Therefore, even when the substrate 202 containing amorphous glass is used, the n-type cladding layer 220, the p-type cladding layer 224, and the emission layer 222 can be formed without deformation of or damage to the substrate 202. At this time, the rotary targets 130 containing the materials contained in the films to be formed are used, and the quantum well structure for realizing high emission efficiency in the emission layer as well as the n-type cladding layer 220 and the p-type cladding layer 224 can be precisely formed by using the sputtering apparatus 100. For example, focusing on FIG. 8A to take an example, the n-type cladding layer 220 corresponds to the film 152-1 shown in FIG. 8A, the emission layer 222 corresponds to the films 152-2 to 152-5 shown in FIG. 8A, and the p-type cladding layer 224 corresponds to the film 152-6 shown in FIG. 8A. In particular, the emission layer 222 having such an extremely small thickness is formed by the sputtering apparatus 100 and the deposition method described above, by which the thickness thereof can be precisely controlled. Hence, it possible to mass-produce the light-emitting diodes 200 with excellent properties.

### (2) Transistor

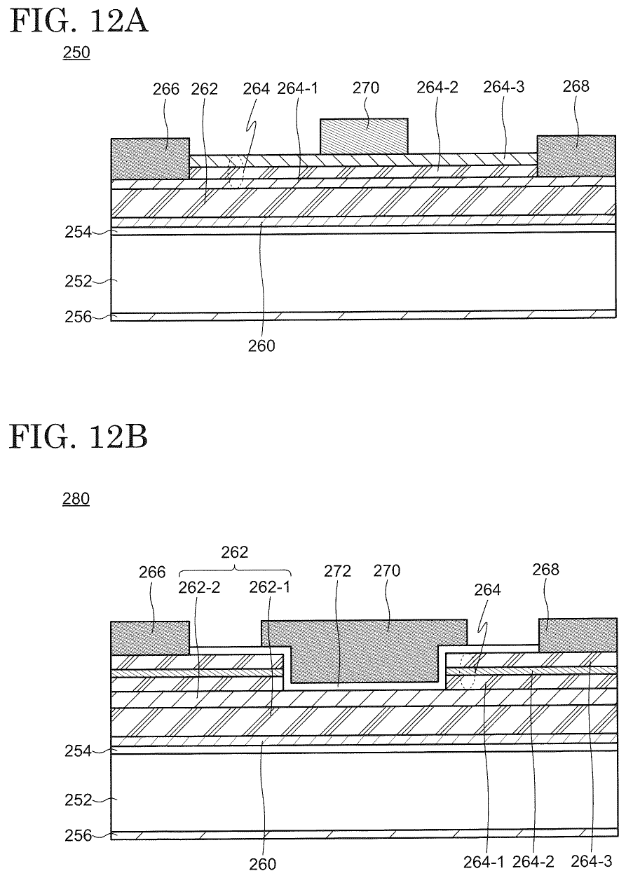

A schematic cross-sectional view of an illustrative transistor 250 fabricated using the sputtering apparatus 100 is shown in FIG. 12A. The transistor 250 shown in FIG. 12A is a high electron-mobility field-effect transistor and includes a substrate 252 as well as a buffer layer 260 and an active layer 262 (also called an electron-traveling layer) over the substrate 252. The transistor 250 further includes an electron-supplying layer 264 over the active layer 262 as well as a gate electrode 270 and a pair of terminals (first terminal 266 and second terminal 268) located over the active layer 262 and electrically connected to the active layer 262 and the electron-supplying layer 264. The first terminal 266 and the second terminal 268 may be in contact with the active layer 262 or may be located over the active layer 262 through the electron-supplying layer 264 as shown in FIG. 12A. Hereinafter, these components will be described below, but the explanation of the substrate 252, the overcoat 254, the undercoat 256, and the buffer layer 260 will be omitted because these components are similar to the corresponding components of the light-emitting diode 200 described above.

The stack of the active layer 262 and the electron-supplying layer 264 forms a source/drain current path when the transistor 250 is driven. The active layer 262 and the electron-supplying layer 264 include a Group 13 element and a Group 15 element. For example, the active layer 262 and the electron-supplying layer 264 may each include a gallium nitride-based or gallium arsenide-based compound semiconductor. In one example, the active layer 262 may be configured to include undoped gallium nitride, and the electron-supplying layer 264 may be composed of a first electron-supplying layer 264-1 containing undoped aluminum gallium nitride, a second electron-supplying layer 264-2 containing undoped gallium nitride, and a third electron-supplying layer 264-3 containing p-type indium gallium nitride.

The buffer layer 260, the active layer 262, and the electron-supplying layer 264 can be formed using the sputtering method within the sputtering apparatus 100 described above. Therefore, film deposition at the high temperatures required by epitaxial growth using the MOCVD method is not required, and even when the substrate 252 containing amorphous glass is used, these layers can be formed without deformation of or damage to the substrate 252. Furthermore, crystallization of the active layer 262 and the electron-supplying layer 264 is promoted in the c-axis direction by the buffer layer 260 serving as a base film thereof. Even when the sputtering method is used to form the active layer 262 and the electron-supplying layer 264, high c-axis orientation can also be achieved in these layers. As a result, transistors with high field mobility can be provided.

The first terminal 266, the second terminal 268, and the gate electrode 270 include a metal such as aluminum, gold, silver, tantalum, molybdenum, titanium, and copper or an alloy containing one or a plurality of the above metals. Although not illustrated, a gate insulating film may be provided between the electron-supplying layer 264 and the gate electrode 270 as an optional component. The gate insulating film includes, for example, a silicon-containing inorganic compound such as silicon oxide and silicon nitride or a so-called high-k material such as hafnium silicate, zirconium silicate, hafnium oxide, and zirconium oxide. Although these components may be formed by a vacuum evaporation method, an electron beam evaporation method, or a CVD method, these components can also be formed by the sputtering method using the sputtering apparatus 100 described above.

The formation of each component of the transistor 250, especially, the formation of the active layer 262 and the buffer layer 260 in addition to the electron-supplying layer 264 having an extremely small thickness with the sputtering apparatus 100 and the deposition method described above enables the precise control of the thicknesses thereof. For example, taking an example focusing on the configuration shown in FIG. 12A, the active layer 262 corresponds to the film 152-1 or the film 152-6 shown in FIG. 8A, and each layer structuring the electron-supplying layer 264 corresponds to the films 152-2 to 152-5. Thus, in particular, the formation of each layer structuring the electron-supplying layer 264 having an extremely small thickness with the sputtering apparatus 100 and the deposition method described above enables precise control of the thicknesses of thereof. Hence, it is possible to efficiently mass-produce the transistor 250 having excellent characteristics.

Transistors manufactured using the sputtering apparatus 100 are not limited to the transistor with the structure shown in FIG. 12A. For example, the active layer 262 may have a two-layer structure as demonstrated in a transistor 280 shown in FIG. 12B. In this case, the active layer 262 may be composed of, for example, a first active layer 262-1 containing undoped gallium nitride and a second active layer 262-2 containing undoped aluminum gallium nitride. There is also no restriction on the configuration of the electron-supplying layer 264. For example, the electron-supplying layer 264 may be configured as a stacked member including a first electron-supplying layer 264-1 containing undoped gallium nitride, a second electron-supplying layer 264-2 containing n-type gallium nitride, and a third electron-supplying layer 264-3 containing undoped gallium nitride. The gate insulating film 272 is disposed between the active layer 262 and the gate electrode 270. The gate insulating film 272 may be configured to include aluminum oxide, a silicon-containing inorganic compound, or the high-k material describe above.

In the transistor 280, not only the buffer layer 260, the gate insulating film 272, the gate electrode 270, the first terminal 266, and the second terminal 268, but also the extremely thin active layer 262 which determines the characteristics of the transistor 280 can be formed by a sputtering method using the aforementioned sputtering apparatus 100. For example, taking an example focusing on the structure shown in FIG. 12B, each layer constituting the active layer 262 corresponds to the film 152-1 or 152-6 shown in FIG. 8A, and each layer constituting the electron-supplying layer 264 corresponds to the films 152-2 to 152. In particular, the formation of each layer constituting the electron-supplying layer 264 and having an extremely small thickness by the sputtering apparatus 100 and the deposition method described above enables the precise control of the thickness thereof. Therefore, these components can be precisely formed, and the transistor 280 with highly controlled characteristics can be mass-produced.

Although an explanation is omitted, the above-mentioned sputtering apparatus 100 and the deposition method using the sputtering apparatus 100 can be utilized not only for the fabrication of the above-mentioned semiconductor devices but also for the fabrication of a variety of configurations such as wirings, terminals, capacitor elements, and electrodes necessary for driving semiconductor devices.

The aforementioned modes described as the embodiments of the present invention can be implemented by appropriately combining with each other as long as no contradiction is caused. Furthermore, any mode which is realized by persons ordinarily skilled in the art through the appropriate addition, deletion, or design change of elements or through the addition, deletion, or condition change of a process on the basis of each embodiment is included in the scope of the present invention as long as they possess the concept of the present invention.

It is understood that another effect different from that provided by each of the aforementioned embodiments is achieved by the present invention if the effect is obvious from the description in the specification or readily conceived by persons ordinarily skilled in the art.

What is claimed is:

1. A deposition method comprising:
performing sputtering on a plurality of rotary targets arranged so that rotation axes thereof are parallel to one another while moving a substrate in a direction perpendicular to the rotation axes,
wherein the plurality of rotary targets is each arranged on one side of the substrate, and
the plurality of rotary targets includes a first rotary target and a second rotary target having a smaller radius than the first rotary target.

2. The deposition method according to claim 1,
wherein the plurality of rotary targets is arranged so that the maximum distance between two of the plurality of rotary targets is longer than a length of the substrate in a longitudinal direction.

3. The deposition method according to claim 1,
wherein the first rotary target and the second rotary target are arranged so that a distance from the rotation axis of the second rotary target to the substrate is shorter than a distance from the rotation axis of the first rotary target to the substrate.

4. The deposition method according to claim 1,
wherein each of the plurality of rotary targets comprises a backing tube and a tubular coating material covering the backing tube, and
the coating materials of the first rotary target and the second rotary target are different from each other.

5. The deposition method according to claim 1,
wherein each of the plurality of rotary targets comprises a backing tube configured to be supplied with a potential and a tubular coating material covering the backing tube, and
a time for supplying the potential to the backing tube of the first rotary target is longer than that to the backing tube of the second rotary target.

6. The deposition method according to claim 1,
wherein each of the plurality of rotary targets comprises a backing tube configured to be supplied with a potential and a tubular coating material covering the backing tube, and
the potential is alternately applied to the backing tubes of two adjacent rotary targets.

7. The deposition method according to claim 1,
wherein each of the first rotary target and the second rotary target comprises a backing tube configured to be supplied with a potential and a tubular coating material covering the backing tube, and
the coating materials of the first rotary target and the second rotary target contain a gallium nitride-based compound semiconductor.

8. The deposition method according to claim 1,
wherein the plurality of rotary targets further includes a third rotary target having a smaller radius than the first rotary target and adjacent to the second rotary target,
each of the second rotary target and the third rotary target comprises a backing tube configured to be supplied with a potential and a tubular coating material covering the backing tube, and
the coating materials of the second rotary target and the third rotary target contain a gallium nitride-based compound semiconductor with compositions different from each other.

9. The deposition method according to claim 1,
wherein each of the plurality of rotary targets comprises a backing tube and a tubular coating material covering the backing tube, and
the coating material of at least one of the plurality of rotary targets has a first half-tube section and a second half-tube section containing different materials.

10. The deposition method according to claim 1,
wherein the sputtering is performed while reversibly moving the substrate.

11. A sputtering apparatus comprising:
a chamber;
a substrate stage in the chamber;
a plurality of target holders arranged in the chamber and each configured to hold a rotary target; and
a moving mechanism in the chamber,
wherein the plurality of target holders is each arranged on one side of the substrate stage so that rotation axes of the rotary targets are parallel to one another,
the moving mechanism is configured to move the substrate stage in a direction perpendicular to the rotation axes,
the plurality of target holders includes a first target holder and a second target holder, and
a radius of the rotary target to be held by the second rotary target is smaller than a radius of the rotary target to be held by the first rotary target.

12. The sputtering apparatus according to claim 11,
wherein the plurality of target holders is arranged so that the maximum distance between two of the plurality of target holders is longer than a length of the substrate in the direction.

13. The sputtering apparatus according to claim 11,
wherein the first rotary target and the second rotary target are arranged so that a distance from the rotation axis of the rotary target to be held by the second target holder is shorter than a distance from the rotation axis of the rotary target to be held by the first target holder to the substrate holder.

14. The sputtering apparatus according to claim 11,
wherein the moving mechanism is configured to reversibly move the substrate stage.

15. A rotary target comprising:
a backing tube; and
a coating material covering the backing tube,
wherein the coating material has n 1/n-tube sections arranged to surround the backing tube,
the 1/n-tube sections respectively contain materials different from one another, and
n is a natural number equal to or greater than 2.

16. The rotary target according to claim 15,
wherein the coating materials contain a gallium nitride-based material.
